(19) United States
(12) Patent Application Publication
(10) Pub. No.: US 2005/0154947 A1
(43) Pub. Date: Jul. 14, 2005

(54) Microcomputer And Method For Debugging Microcomputer

(75) Inventor: Masayoshi Taniguchi, Shiga-ken (JP)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 10/905,227

(22) Filed: Dec. 22, 2004

(30) Foreign Application Priority Data
Dec. 25, 2003 (JP) 2003-429853

(51) Int. Cl. G01R 31/28

(52) U.S. Cl. 714/726

(57) ABSTRACT

The System on a Chip (SoC) according to the present invention provides debugging by reading or rewriting the contents of an arbitrary register within an SoC by a level-sensitive scan design (LSSD) scan test, and includes a scan chain for scan tests that connects a plurality of latch circuits in chain form and a debug circuit for, while performing a scan test on the scan chain, specifying a specific latch circuit constituting the scan chain and reading data from the latch circuit. The scan chain gives output back to the input of the first latch circuit, thus forming a feedback loop. There exist a plurality of such scan chains, each consisting of the same number of latch circuits, including latch circuits for performing a scan test and dummy latch circuits for making the number of latch circuits constituting the scan chain identical among all of the scan chains.

### FIELD OF THE INVENTION

The present invention relates to a debugging method in which a logic design of SoC (System on a Chip) is tested and a mechanism for debugging.

### BACKGROUND ART

The advances in the semiconductor integration technology has increased chip density and thus the number of gates that can be integrated onto one chip has been drastically increased. Accordingly, more and more ASICs (Application Specific Integrated Circuits), which are designed and manufactured for specific applications, are being implemented as SoC (System on a Chip) on which main functions of a computer such as a processor, a memory, and peripherals are integrated on a single chip. An ASIC implemented as a SoC requires a considerably smaller space and consumes lower power compared with a multiple-chip system with equivalent capabilities.

Unlike circuits implemented on a printed-circuit board, circuits on SoC cannot directly be checked because various types of devices are integrated on the single chip. For example, values on a data bus in circuits on a printed-circuit board can be directly read by means of a logic analyzer and oscilloscope and the state of a particular signal can readily be checked, whereas such checks, which are performed by applying a probe to terminals, cannot be performed on an ASIC in SoC form (hereinafter simply referred to as ASIC).

LSSD (level-sensitive scan design) scan tests using LSSD latches (flip-flops) are widely used for inspecting chips for defects in manufacturing ASIC (see Published Unexamined Patent Application No. JP 10123222 A2, for example).

FIG. 8 shows a configuration of LSSD latches; FIG. 9 is a diagram illustrating a scan chain for conducting an LSSD scan test.

As shown in FIG. 8, the LSSD latch 200 consists of two D-latches: a master latch 201 and a slave latch 202. The master latch 201 has an A-clock input, a scan input controlled by A-clock, a C-clock input and a data input controlled by C-clock. Connected to the slave latch 202 is B-clock. When B-clock is high, data is input from the master latch 201 into the slave latch 202.

In normal operation, A-clock is held low and data is held by using B-clock and C-clock. In an LSSD scan test, A-clock and B-clock are used for inputting test data and outputting the results of the test.

In an LSSD scan test, all LSSD latches (indicated as FF in FIG. 9) on the chip are connected through a plurality of scan chains and a test pattern is input through the LSSD latches (scan-in), as shown in FIG. 9. The result is held in the LSSD latches and also output from the chip through the scan chains (scan-out). The output result is compared with a predetermined expected value to determine whether the chip is defective or non-defective.

### SUMMARY OF THE INVENTION

As described above, a probe cannot be connected to a data bus in an ASIC in SoC form to read the data electrically. Therefore, it is considerably difficult to detect the cause of a bug in a developed ASIC.

LSSD-latch (flip-flop)-based scan tests are intended to determine whether chips are properly manufactured. They do not determine whether logic designs of ASIC themselves are correct or not. Accordingly, they are not suitable for locating the cause of a bug in ASIC.

Furthermore, execution of such tests changes the contents of all LSSD latches. Consequently, the chip cannot be retested in the same state.

An object of the present invention is to solve these problems and implement an LSSD scan test to debug a SoC.

Another object of the present invention is to provide means for suspending a program running on SoC at any point of time to read or rewrite the content of any register in the SoC.

Yet another object of the present invention is to read or rewrite the content of such a register without corrupting the content of the register.

The present invention which achieves these objects is implemented as SoC including a scan chain consisting of a plurality of latch circuits connected in chain form for performing a scan test, and a debug circuit which specifies a particular latch circuit constituting the scan chain to read data from said latch circuit while performing a scan test on the scan chain.

In particular, the scan chain returns its output to the input of the first latch circuit to form a feedback loop. A plurality of such scan chains are provided, which are respectively identical in the number of constituent latch circuits. Each of the scan chain includes latch circuits used in a scan test and dummy latches circuit for making the number of latch circuits constituting the scan chains identical to one another.

More particularly, the debug circuit includes: a first register for holding data specifying the particular latch circuit in the scan chain, the data being the count value of a clock used in the scan test; a second register for holding data read from the particular latch circuit specified by the data held in the first register; and a control circuit sending a control signal to the scan chain for outputting data to the second register at a timing obtained from the count value of a clock used in the scan test and the data held in the first register.

The debug circuit may further include a third register for holding data to be written in the particular latch circuit specified by the data held in the first register. In that case, the control circuit sends the data held in the third register to the scan chain at a timing obtained from the clock count value used in the scan test and the data held in the first register.

Another SoC according to the present invention includes a scan chain consisting of a plurality of latch circuits connected in a chain for performing a scan test; clock supplying means for generating and supplying to the scan chain a clock for sequentially shifting data in the latch circuits constituting the scan chain along the scan chain; and data reading means for reading data from the latch circuits in the scan chain at a timing obtained on the basis of the count value of the clock.

The SoC may further include other components such as data writing means for sending data to be written in the latch circuit to the scan chain at a timing obtained from the count value of the clock and evaluating means for evaluating data read by data reading means from a latch circuit.

Preferably, the scan chain returns a scan-out, which is an output from the scan chain, to a scan-in, which is the input of the first latch circuit constituting the scan chain to form a feedback loop, and the clock supplying means generates and supplies to the scan chain a number of clocks required for the data in the latch circuits to loop back along the feedback loop, that is, as many clocks as the number of the latch circuits constituting the scan chain (scan chain lengths).

Another implementation of the present invention that achieves the object described above is a method for debugging an electronic circuit containing a scan chain consisting of a plurality of latch circuits connected in a chain for performing a scan test. The debugging method includes the steps of: shifting data in the latch circuits constituting the scan chain sequentially in accordance with a predetermined clock; reading data from one of the latch circuits that is determined by the count value of the clock and storing the data read from the latch circuit in a data read register; and reading by a computer the data stored in the data read register.

The debugging method may further include the step of replacing the data in the latch circuit determined by the count value of the clock with data stored in a data write register.

In particular, in order to shift the data in the latch circuits, the system clock is first stopped and a predetermined clock used for shifting the data is generated, then, in order to read the data by the computer, the predetermined clock used for shifting the data is stopped and the system clock is restarted.

According to the present invention configured as described above, data in the latch circuits in a scan chain is shifted by using a predetermined clock, the data in a latch circuit can be read or rewritten at a given timing, and thus the state of a particular circuit within the SoC can be checked and debugged.

Furthermore, according to the present invention, on completion of a scan test the data in the latch circuits in the scan chain can be returned to the original value, and the data in the latch circuits can be read or rewritten without corrupting the content of the latch circuits.

### BRIEF DESCRIPTION OF THE DRAWINGS

The invention will be better understood from the following detailed description with reference to the drawings, in which:

FIG. 1 shows a configuration of a SoC (System on Chip) implementing debugging by using scan chains according to the present embodiment;

FIG. 2 shows a configuration of a scan chain used in a scan test according to the present embodiment;

FIG. 3 shows a configuration of a control circuit of a debug circuit according to the present embodiment;

FIG. 4 is a timing chart of A-clock, B-clock, and C-clock output from a control circuit according to the present embodiment;

FIG. 5 is a timing chart of a write clock output from the control circuit according to the present embodiment;

FIG. 6 is a diagram illustrating state transition of the debug circuit controlled by a state machine according to the present embodiment;

FIG. 7 is a flowchart illustrating the overall flow of operation for reading the value from a desired LSSD latch constituting a scan chain in debugging according to the present embodiment;

FIG. 8 shows a configuration of an LSSD latch; and

FIG. 9 is a diagram illustrating a scan chain for conducting a LSSD scan test according to the prior art.

### DETAILED DESCRIPTION OF THE PREFERRED EMBODIMENTS

The best mode (hereinafter referred to as the embodiment) for implementing the present invention will be described in detail with reference to the accompanying drawings, which are not necessarily drawn to scale.

In a scan test according to the present embodiment, the following items should be implemented in order to determine that a logic design of a SoC is correct to perform debugging.

The content of any LSSD latch (flip-flop) constituting a scan chain can be read.

The content of any LSSD latch constituting a scan chain can be rewritten.

Reading or writing the content of a desired LSSD latch must not change the contents of other LSSD latches.

After the contents of an LSSD latch is read in the test, a program suspended because of the test can be resumed.

To implement the items listed above, the following four conditions must be met in the configuration of the present embodiment.

1. All scan chains should have a feedback loop for returning scan-out data to the scan-in.

This allows the values in the LSSD latches constituting a scan chain to shift sequentially in a scan test. After the values in all LSSD latches in the feedback loop are shifted, the value in each LSSD latch returns to the original value. Thus, the values in the LSSD latches are not corrupted.

2. All scan chains should have the identical length (the same number of LSSD latches).

This can equalize the times required to return the values in the LSSD latches in all scan chains to the original values. That is, the clock count required for scan tests can be equalized. This condition, combined with condition 1, can return the values in all LSSD latches in all scan chains to the original value at the same time after the value in the LSSD latches loops back through the feedback loop of scan chains in a scan test.

3. Registers for reading and writing data in the LSSD latches (scan chain data) in a scan chain are provided so as to allow scan chain data to be held or rewritten at a given timing during a scan test.

4. The same number of A-clocks and B-clocks (used for shifting the values in the LSSD latches along a scan chain) used in a scan test as that of the LSSD latches constituting a scan chain is generated in one scan test.

This condition, combined with conditions 1 and 2, allows the values in the LSSD latches in each scan chain to loop back through the feedback loop in a scan chain so that the values in all LSSD latches in all scan chains return to the original values on completion of the scan test. Therefore, the execution of the program suspended because of the scan test can be resumed on completion of the test.

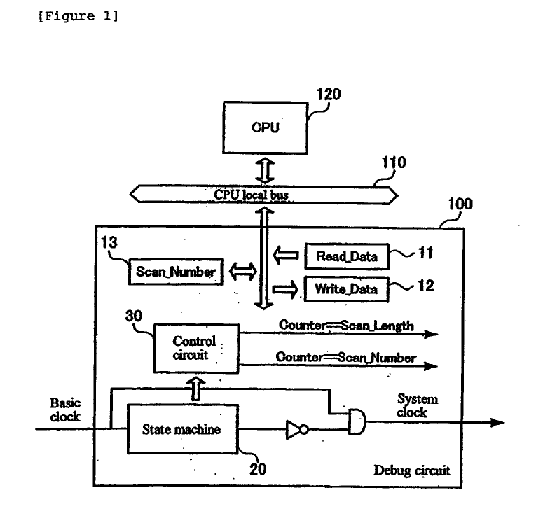

FIG. 1 shows a configuration of SoC (System on a Chip) that implements debugging by using scan chains according to the present invention.

As shown in FIG. 1, a debug circuit 100 is provided on the SoC of the present invention. The debug circuit 100 is connected to a CPU 120 through a CPU local bus 110 and controls scan chains (not shown) to debug the devices (not shown) provided on a SoC chip.

As shown in FIG. 1, the debug circuit 100 in the present embodiment includes a Read_Data register 11, a Write_Data register 12, a Scan_Number register 13 for reading and writing data in the LSSD latches in a scan test, and a state machine 20 for managing the state transition of the debug circuit 100, including state transition during a scan test, and a control circuit 30 for conducting a scan test.

A basic clock is input into the debug circuit 100 in FIG. 1 and a system clock is output from the debug circuit 100 in accordance with the basic clock. The basic clock herein is equivalent to a typical system clock generated by phase locked loop (PLL) circuits. However, a system clock in the present embodiment is stopped while a scan test is being conducted under the control of the debug circuit 100, as will be described later. Therefore, the clock before being input into the debug circuit 100 is referred to as the basic clock to distinguish it from the system clock suspended during the scan test.

In the configuration as described above, the Read_Data register 11 is used for reading data from a particular LSSD latch in a scan chain. When the value of a counter 31 of the control circuit 30 matches the value in a Scan_Number register 13, which will be described later, the Read_Data register 11 holds scan chain data. Furthermore, the Read_Data register 11 is connected onto the CPU local bus 110 so that the CPU 120 can read the content of (data held in) the Read_Data register 11.

The Write_Data register 12 is used for writing data into a particular LSSD latch in a scan chain. When the value of the counter 31 of the control circuit 30, which will be described later, matches the Scan_Number register 13, the value in the Write_Data register 12 is held in the LSSD latch in the scan chain. The Write_Data register 12 is connected onto the CPU local bus 110 so that the CPU 120 can write data (a value to be written in an LSSD latch in a scan chain) into the Write_Data register 12.

Written into the Scan_Number register 13 is data (the scan number) indicating the position of a particular target LSSD latch in the sequence in a scan chain from which data is to be read or into which data is to be written. The Scan_Number register 13 is connected onto the CPU local bus 110 so that the CPU 120 can write data (the scan number) into the Scan_Register 13.

The state machine 20 has four stages (states), “idle,” “stop,” “test” and “restart,” to control state transition of the debug circuit 100. The state transition will be detailed later.

The control circuit 30 generates and outputs A-clock, B-clock, C-clock, and a write clock (Write_Clk) used in a scan test while the state machine 20 is in the test stage. It also manages the position of the target LSSD latch in a scan test and the end-of-test timing. The configuration and functions of the control circuit will be detailed later.

A scan chain used in a scan test according to the present embodiment will be described below.

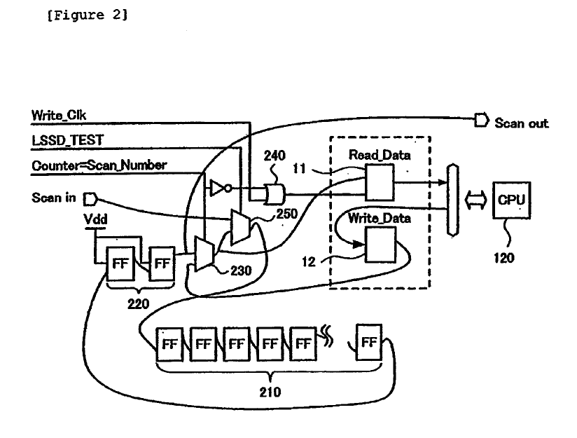

FIG. 2 shows a configuration of a scan chain used in a scan test according to the present embodiment. Although a typical ASIC has 16 or more scan chains in order to reduce the time required for a test, a configuration of only one scan chain is shown because every scan chain has the same configuration.

As shown in FIG. 2, the scan chain according to the present embodiment includes a chain 210 of LSSD latches to be tested and dummy LSSD latches 220 not to be tested, and a multiplexer 230.

As shown in FIG. 2, the scan-out is returned to the scan-in of the first LSSD latch in the chain 210 so that data read from the LSSD latch can be re-written into the LSSD latch. This allows the above-described condition “The scan chains should have a feedback loop for returning scan-out data to the scan-in” to be met. Because the scan chain forms a feedback loop, the value in each LSSD latch can be shifted and looped back along the feedback loop in a scan chain, rather than inputting a test pattern from an external source through the scan-in. Thus, the test can be conducted nondestructively.

The dummy LSSD latches 220 are provided so that the scan chains 210 in SoC have the same length (the same number of LSSD latches). In the case of conventional scan testing for determining whether chips are non-defective, the lengths of the scan chains are also made about the same because, if the scan chains had different lengths, the testing would require more time in proportion to the length of the longest scan chain. However, there may be an error of 1 or two bits. Therefore, dummy LSSD latches 220 are provided as needed in order to make the lengths of the scan chains exactly the same. In the example shown in FIG. 2, two dummy LSSD latches 220 are provided.

The dummy LSSD latches ensure that the data in the LSSD latches in all scan chains returns to the original LSSD latches at the same time on completion of the test in the present embodiment. If the scan chains have different lengths, the clock count required for returning the data to the original LSSD latches on completion of the scan test would vary among the scan chains and the data in all scan chains cannot be recovered at the same time. Therefore, dummy LSSD latches 220 are included as appropriate to make the lengths of the scan chains equal. Thus, the above-described condition “All scan chains should have the same length” is met.

The multiplexer 230 is a multiplexer for writing data into a particular LSSD latch in the chain 210. Input into the multiplexer 230 are data from the LSSD latches in the scan chain (at the position of the scan-out in FIG. 2) and data from the Write_Data register 12. Then, the value in the LSSD latches is shifted along the feedback loop of the scan chain. When the value in the target LSSD latch is input into the multiplexer 230, the output of the multiplexer 230 is changed under the control of the control circuit 30 of the debug circuit 100 and the value in the Write_Data register 12 is selected instead of the value in the LSSD latch. After the value in each LSSD latch loops back along the feedback loop of the scan chain, the value in the Write_Data register 12 is written into the target LSSD latch. The output of the multiplexer 230 is held in the Read_Data register 11 under the control of the control circuit 30 of the debug circuit 100 (by a write clock and a scan length signal (detailed later) input through an OR circuit 240). Thus, the above-described condition “To allow scan chain data to be held or rewritten” is met.

An additional multiplexer 250 shown in FIG. 2 is used for inputting in a scan chain a test pattern from an external pin when conducting a conventional scan test for determining whether the chip is non-defective and therefore does not function in a test of the present embodiment.

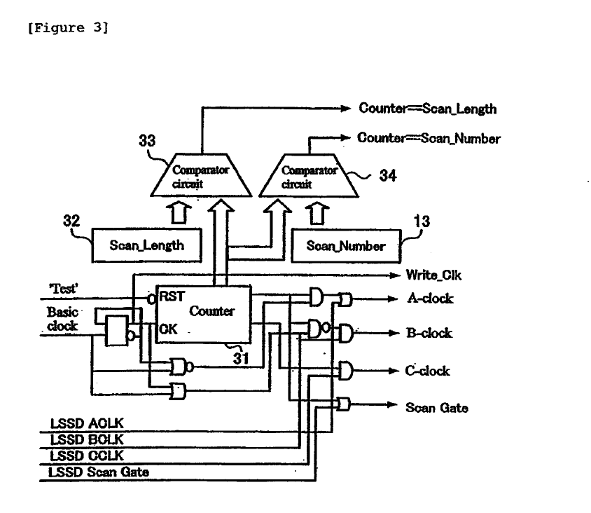

FIG. 3 shows a configuration of the control circuit 30 shown in FIG. 1.

As shown in FIG. 3, the control circuit 30 includes a counter 31, a register 32 holding the length of a scan chain (Scan_Length), a comparator circuit 33 for comparing the value of the counter 31 with the value in the register 32, and a comparator circuit 34 for comparing the value of the counter 31 with the scan number (Scan_Number) held in the Scan_Number register 13 shown in FIG. 1.

As shown in FIG. 3, the control circuit 30, in accordance with the basic clock, generates and sends out A-clock, B-clock, and C-clock used for shifting scan chain data along the feedback loop and a write clock (Write_Clk) used for holding the scan chain data in the Read_Data register 11. The write clock is generated by dividing the basic clock by two before being sent.

The counter 31 counts up the basic clocks while the debug circuit 100 is in the test stage which is maintained in the state machine 20; the counter 31 is reset in other stages.

The comparator circuit 33 compares the count value of the counter 31 with the value held in the register 32. When the count value becomes equal to the length of the scan chain, the comparator circuit 33 drives high the scan length signal (Counter==Scan_Length) indicating this timing. The scan length signal is input into the state machine 20. On condition of this, the test stage of the debug circuit 100 will end. Because the scan chain length held in the register 32 is a fixed value, it may be stored in a non-volatile memory such as a ROM (Read Only Memory) instead of the register.

The comparator circuit 34 compares the count value of the counter 31 with the scan number held in the Scan_Number register 13. When the count value becomes equal to the scan number, the comparator circuit 34 drives high a target signal (Counter==Scan_Number) indicating this timing. The target signal is input into the Read_Data register 11 as shown in FIG. 2 to indicate the timing of holding the scan chain data. It is also used as a signal for switching the multiplexer 230 in a scan chain to indicate the timing of writing the value held in the Write-Data register 12.

Among A-clock, B-clock, and C-clock, A-clock and B-clock are output in accordance with the basic clock while the debug circuit 100 is in the test stage and the counter 31 is operating. Therefore, the clock counts of A-clocks and B-clocks are equal to the length of the scan chain. C-clock, on the other hand, is forced and held low while the debug circuit 100 is in the test stage. These clock signals are of the same type as clock signals input from an external source in a conventional scan test for determining whether a chip is non-defective (LSSD ACLK, LSSD BCLK, and LSSD CCLK in FIG. 3). However, because such clock signals from an external source cannot be used during a scan test for debugging according to the present embodiment, and each value is fixed, they are generated in the debug circuit 100.

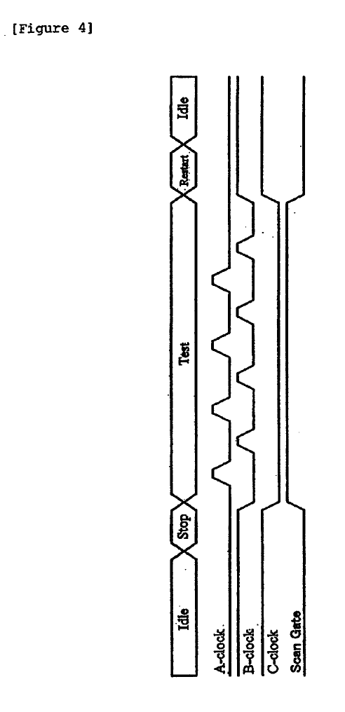

FIG. 4 is a timing chart of A-clock, B-clock, and C-clock.

As shown in FIG. 4, A-clock is fixed at 0, B-clock is fixed at 1, C-clock is fixed at 1, and a scan gate is fixed at 0 while the debug circuit 100 is not in the test stage (the SoC in normal operation). In the test stage (in a scan test), on the other hand, A-clock and B-clock become pulse signals that do not overlap one another (Non-overlap pulses). The counts of clocks are equal to the length of the scan chain as described above. Therefore, shifting the value in each LSSD latch along the scan chain forming the feedback loop in accordance with A-clock and B-clock means that the values in all LSSD latches constituting the scan chain loop back along the feedback loop to the original LSSD latches after the test stage ends and A-clock and B-clock supply stops.

While the debug circuit 100 is in the test stage, C-clock is held low=0 (inactive) as described above and the value of the scan gate is held at 1. Because C-clock, which is a function clock, is held at 0, corruption of the data in the LSSD latches by data from an external source flowing into the scan chain is prevented during a scan test.

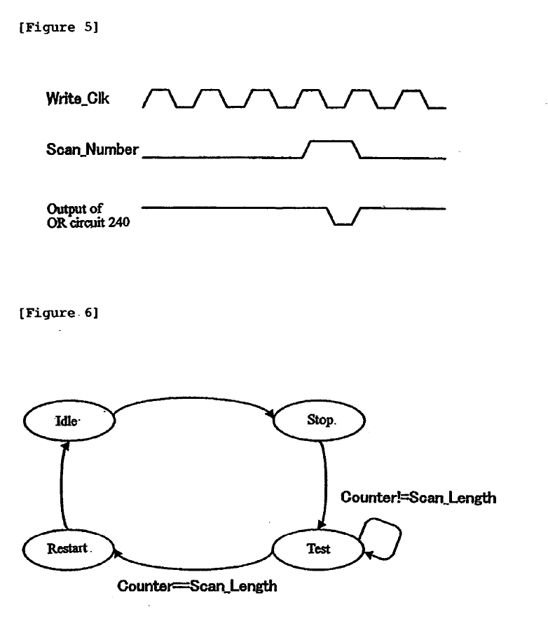

FIG. 5 is a timing chart of the write clock.

As described earlier, the write clock is output as a pulse signal having a half frequency of the basic clock while the debut circuit 100 is in the test stage. When the clock count becomes equal to the scan number, a target signal is output from the comparator circuit 34, which forces low=0 the output of the OR circuit 240 connected to the Read_Data register 11 as shown in FIG. 2. This causes data output from the multiplexer 230 at this point of time, that is, the value in the target LSSD latch, to be stored in the Read_Data register 11.

FIG. 6 is a diagram illustrating state transition of the debug circuit 100 controlled by the state machine 20.

As shown in FIG. 6, the state machine 20 has four stages (states), “idle,” “stop,” “test,” and “restart.” Once the SoC is reset, the state machine enters the idle stage. When a read instruction for reading the data in the LSSD registers in the scan chain is issued from the CPU 120, the state machine 20 changes from the idle stage to the stop stage. In this stage, the system clock output from the debug circuit 100 shown in FIG. 1 is stopped. This causes the circuits other than the debug circuit 100 and the scan chains controlled by the debug circuit 100 stop operating.

Then, when the state machine enters the test stage, clock control is performed by the control circuit 30 as described above to allow data to be written or read into or from a desired LSSD latch in the scan chain. In the test stage, the values in the LSSD latches constituting the scan chain are shifted in turn in accordance with the generated clock. When shifts as many as the number of the LSSD latches (scan chain lengths) in the scan chain have been made, data in each LSSD latch after rounding the feedback loop of the scan chain returns to the original value. Then, the test stage ends. That is, if the number of the LSSD latches in the scan chain is 3,000, then the test stage ends after 3,000 scan shifts.

After the test stage ends, the state machine 20 enters the restart stage. In the restart stage, the suspended system clock is restarted to allow SoC to perform normal operation. Then, it returns to the idle stage and the process ends.

In the state transition described above, the system clock is suspended during the period from the stop stage to the end of the test stage to cause the circuits other than the debug circuit 100 and the scan chains controlled by the debug circuit 100 stop operating in order to prevent corruption of data in the scan chain due to a malfunction of the system during the scan test. Because C-clock for the LSSD latches are inactive during a scan test, data in a portion of the circuitry on SoC that is in normal operation is not lost. However, if components such as CPU 120 had been operating during a scan test, an input signal such as an interrupt signal could be influenced by the scan test and cause a malfunction of CPU 120. Such a malfunction is prevented by suppressing the system clock.

The following is the description of a debugging procedure according to the present embodiment configured as described above.

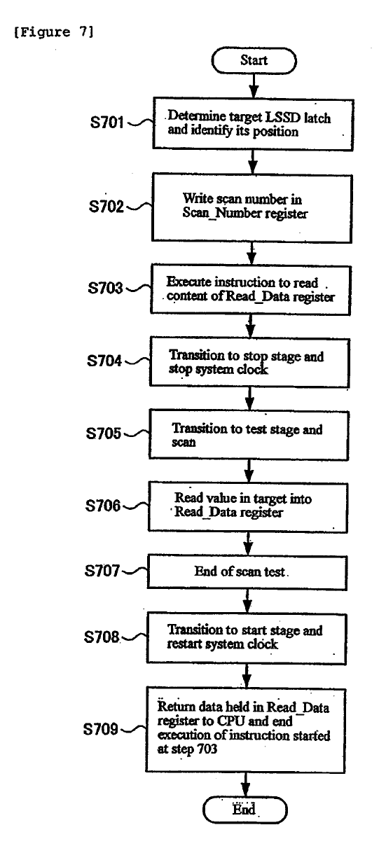

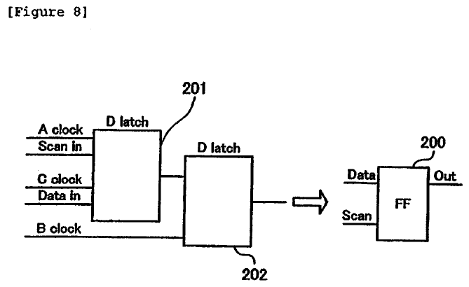

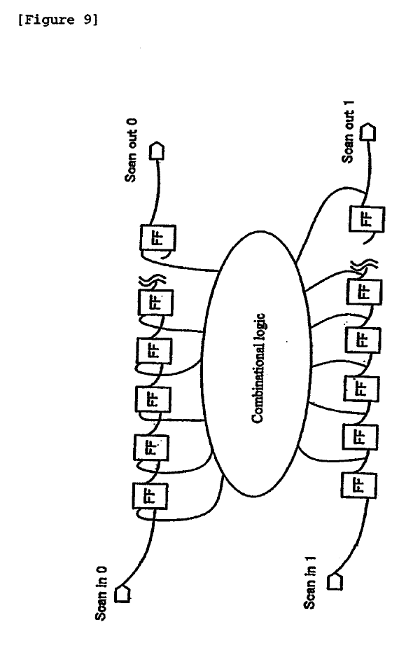

FIG. 7 is a flowchart illustrating the overall flow of operation for reading data from a desired LSSD latch constituting a scan chain in debugging according to the present embodiment.

As shown in FIG. 7, the CPU 120 determines a target LSSD latch (from which data is to be read) and identifies the position of the LSSD latch in the scan chain (what n-th from the first LSSD latch in the chain) in a preliminary step (step 701). This position can be identified by tracing the scan chain back from the scan-out.

When the CPU 120 identifies the position of the target LSSD latch, the CPU 120 writes the scan number (the number from the first LSSD latch in the scan chain) indicating the position into the Scan_Number register 13 (step 702). It then executes an instruction to read the content of the Read-Data register 11 (step 703). When the instruction is executed, the state machine 20 of the debug circuit 100 starts operating and the debug circuit 100 transitions from the idle stage to the stop stage to stop the system clock (step 704).

Then, the debug circuit 100 transitions from the stop stage to the test stage under the control of the state machine 20 and starts to scan all scan chains in SoC (step 705). A-clock and B-clock output from the control circuit 30 shift the values in the LSSD latches in the scan chains in turn. When the count value of the basic clocks by the counter 31 becomes equal to the scan number which has been written in the Scan_Number register 13 at step 702, scan-out data at this point (that is, the value in the target LSSD latch) is read into the Read_Data register 11 (step 706).

The shifting of the values in the LSSD latches by A-clock and B-clock and the counting of the basic clocks by the counter 31 is continued. When the count value of the counter 31 becomes equal to the scan length, the scan test will end under the control of the state machine 20 (step 707).

On completion of the scan test, the debug circuit 100 transitions from the test stage to the start stage under the control of the state machine 20 and restarts the system clock (step 708). Then, the CPU 120 resumes operation and the data held in the Read_Data register 11 at the above-described steps are returned to the CPU 120 and the execution of the instruction started by the CPU 120 at step 703 will end (step 709). After entering the start stage, the debug circuit 100 further transitions to the idle stage under the control of the state machine 20 and stays in the idle stage until the next scan test instruction is executed.

In the operation shown in FIG. 7 and described above, data is read from the target LSSD latch in the scan chain. To write data into the target LSSD latch, the CPU 120 first writes the data to be written in the target LSSD register into the Write_Data register 12 as a preliminary step. Then it executes an instruction to write the data from the Write_Data register 12.

The debug circuit 100 reads the data from the target LSSD register into the Read_Data register 11 in a manner similar to the process from step 704 to step 706. The data read from the scan chain at the same timing as this reading is replaced with the data in the Write_Data register 12 and the data is returned to the scan chain. Thus, the values in the LSSD latches in the scan chain shift sequentially, loop back along the feedback loop and, on completion of the scan test, only the data in the target LSSD latch is changed to the data written in the Write_Data register 12.

As has been described, the mechanism and debugging method of the present embodiment allows the values in all registers within the SoC to be read through the use of the read command of the CPU 120. If the system operates in an unexpected manner when performing a given process under the control of a program for example, the debugger of the CPU 120 can be used to stop the execution of the program at any point to inspect the state of a circuit of interest.

In addition to reading the value in a problem register, a correct value can be rewritten into the register and then the program can be restarted. With this capability, determination can be made as to whether the debugging has been made properly or not.

Furthermore, the content of any register can be corrected under the control of a program. Therefore, if an ASIC in the form of SoC malfunctions due to a bug, the bug may be able to be corrected by inserting a software patch in the program, depending on the nature of the bug. In view of costs of developing an ASIC, the advantage of being capable of debugging instead of redesigning the chip is immeasurable.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

1. A microcomputer comprising:
a scan chain having a plurality of latch circuits connected in chain form for performing a scan test; and
a debug circuit specifying a particular latch circuit constituting said scan chain to read data from said latch circuit while performing the scan test on said scan chain.

2. The microcomputer according to claim 1, wherein said debug circuit specifies a particular latch circuit constituting said scan chain to write data into said latch circuit.

3. The microcomputer according to claim 1, wherein said scan chain returns an output from said scan chain to an input of the first latch circuit constituting said scan chain to form a feedback loop.

4. The microcomputer according to claim 1, wherein a plurality of said scan chains are provided and each of said scan chains comprises the same number of latch circuits.

5. The microcomputer according to claim 4, wherein said scan chains comprise latch circuits used in a scan test and dummy latch circuits for making the number of latch circuits constituting said scan chains identical to one another.

6. The microcomputer according to claim 1, wherein said debug circuit comprises:
a first register for holding data specifying said particular latch circuit in said scan chain, said data being the count value of a clock used in the scan test;
a second register for holding data read from said particular latch circuit specified by the data held in said first register; and
a control circuit sending a control signal to said scan chain for outputting data to said second register at a timing obtained from the count value of a clock used in said scan test and the data held in said first register.

7. The microcomputer according to claim 6, further comprising a third register for holding data to be written in said particular latch circuit specified by the data held in said first register,
wherein said control circuit sends the data held in said third register to said scan chain at a timing obtained from the clock count value of a clock used in said scan test and the data held in said first register.

8. The microcomputer according to claim 1, wherein said scan chain and said debug circuit are implemented on a single integrated circuit together with a circuit to be scan-tested.

9. A microcomputer comprising:
a scan chain consisting of a plurality of latch circuits connected in a chain for performing a scan test;
clock supplying means for generating and supplying to said scan chain a clock for sequentially shifting data in the latch circuits constituting said scan chain along said scan chain; and
data reading means for reading data from the latch circuits in the scan chain at a timing obtained on the basis of the count value of said clock.

10. The microcomputer according to claim 9, further comprising data writing means for sending data to be written in said latch circuit to said scan chain at a timing obtained from the count value of said clock.

11. The microcomputer according to claim 9, wherein said scan chain returns an output from said scan chain to an input of the first latch circuit constituting said scan chain to form a feedback loop; and
said clock supplying means generates and supplies to said scan chain a number of said clocks required for data in said latch circuits to loop back along said feedback loop.

12. The microcomputer according to claim 9, further comprising evaluating means for evaluating data read by said data reading means from said latch circuit read, wherein said scan chain, said clock supplying means, said data reading means, and said evaluating means are implemented on a single integrated circuit.

13. A debugging method for debugging an electronic circuit containing a scan chain consisting of a plurality of latch circuits connected in a chain for performing a scan test, comprising the steps of:
shifting data in the latch circuits constituting said scan chain sequentially in accordance with a predetermined clock;
reading data from one of the latch circuits that is determined by the count value of said clock and storing the data read from said latch circuit in a data read register; and
reading by a computer the data stored in said data read register.

14. The debugging method according to claim 13, further comprising the step of replacing the data in said latch circuit determined by the count value of said clock with data stored in a data write register.

15. The debugging method according to claim 13, wherein said step of shifting data in said latch circuits comprises the steps of:
stopping a system clock; and
generating said predetermined clock used for shifting the data; and
said step of reading said data by a computer comprises the steps of:
stopping said predetermined clock used for shifting the data; and
restarting said system clock.
